(19) United States
(12) Patent Application Publication
(10) Pub. No.: US 2024/0349462 A1
(43) Pub. Date: Oct. 17, 2024

(54) AIR-LIQUID FUSION MODULAR DATA CENTER

(71) Applicant: Hebei Qinhuai Data Co., Limited., Zhangjiakou City (CN)

(72) Inventors: Binghua ZHANG, Zhangjiakou City (CN); Mingjiang LI, Zhangjiakou City (CN)

(21) Appl. No.: 18/633,193

(22) Filed: Apr. 11, 2024

(30) Foreign Application Priority Data
Apr. 14, 2023 (CN) 202310399443.1

(51) Int. Cl. H05K 7/20

(52) U.S. Cl. CPC H05K 7/2079

(57) ABSTRACT

The present disclosure discloses an air-liquid fusion modular data center, including a machine room, a plate-type liquid cooling cabinet, an air-chilled water radiator, a precooling module, and a CDU device. The plate-type liquid cooling cabinet, the air-chilled water radiator, the precooling module, and the CDU device are positioned inside the machine room. A server is installed in the plate-type liquid cooling cabinet, and the air-chilled water radiator is coupled to the precooling module. The air-chilled water radiator forms a cooling water circulation together with a primary side of the CDU device; and a secondary side of the CDU device forms a cooling water circulation together with a cold plate of the plate-type liquid cooling cabinet.

### CROSSREFERENCE TO RELATED APPLICATION

This application claims priority to Chinese Patent Application No. 202310399443.1, titled “AIR-LIQUID FUSION MODULAR DATA CENTER” and filed to the China National Intellectual Property Administration on Apr. 14, 2023, the entire contents of which are incorporated herein by reference.

### TECHNICAL FIELD

The present disclosure relates to the field of data center technology, and more particularly, to an air-liquid fusion modular data center.

### BACKGROUND

With the significant increase of chip computing power, chip power consumption and heat dissipation demands are increased, liquid cooling systems are gradually becoming a choice for new-generation data center cooling systems. Cold plate liquid cooling is widely used as a relatively mature liquid cooling method. Cold plates are attached to larger heating components (such as CPU and GPU), water liquids flow in the cold plates to take away heat from the components. The heat is transferred from a secondary side to a primary side through a coolant distribution unit (CDU), thus ensuring that water quality on the secondary side is not adversely affected by metal corrosion and cenobium while ensuring heat exchange. However, in most cases the plate cooling method requires cooling by means of air (hereinafter referred to as air cooling) to remove the heat from other low-power components (such as hard drives and transformers). Therefore, a concept of air-to-liquid ratio is proposed, i.e. a ratio of air cooling heat to liquid cooling heat. Air cooling and liquid cooling need to act together to dissipate heat from electronic devices.

A common method of the air cooling is a chilled water terminal. That is, heat of air is transferred to the chilled water and then is transferred out of data centers through an air-chilled water heat exchanger. In plate-type liquid cooling rooms, in most cases multiple water systems are required, including liquid cooling secondary systems, liquid cooling primary systems, and chilled water systems. These three systems make water pipes in the data centers complex, requiring larger space to arrange these three pipes separately, especially the latter two.

Design and allocation of various devices in the space are not reasonable enough, resulting in complex structures of water pipe systems, which not only occupies larger building space, but also leads to unstable heat dissipation effects of the data centers and higher energy consumption, further adversely affecting operating efficiency of IT devices. The complex structures of the water pipe systems lead to more complex control scheme, lower safety, higher energy consumption, and unstable operation.

There are many dust particles in the atmosphere, and under the action of air extraction and air return due to long-term use, aluminum fins of fans are filled with dust and dirt, which adversely affects heat exchange between chilled water and hot air, thus having a negative effect on air temperature drop, and leading to a problem where it is not cold indoors although refrigeration is started.

### SUMMARY

To solve existing technical problems, embodiments of the present disclosure provide an air-liquid fusion modular data center. The technical solutions are as follows.

There is provided an air-liquid fusion modular data center, including a machine room, a plate-type liquid cooling cabinet, an air-chilled water radiator, a precooling module, and a CDU device. The plate-type liquid cooling cabinet, the air-chilled water radiator, the precooling module, and the CDU device are positioned inside the machine room. A server is installed in the plate-type liquid cooling cabinet, and the air-chilled water radiator is coupled to the precooling module. The air-chilled water radiator forms a cooling water circulation together with a primary side of the CDU device; and a secondary side of the CDU device forms a cooling water circulation together with a cold plate of the plate-type liquid cooling cabinet. A fourth valve is arranged between a precooling water pump in the precooling module and a precooling water storage tank, a fourth temperature sensor is installed at a liquid outlet end of the precooling water pump, and the fourth valve adjusts a cooling effect of the precooling module on hot air inside the machine room based on the fourth temperature sensor.

Further, the precooling module adopts a double wet film design with upper and lower layers.

Further, the precooling module includes a shell, a precooling surface cooler, an upper precooling wet film, a lower precooling wet film, an upper precooling water distributor, a lower precooling water distributor, a precooling drain pan, the precooling water storage tank, the precooling water pump, the fourth valve, and the fourth temperature sensor. The precooling surface cooler, the upper precooling wet film, the lower precooling wet film, the upper precooling water distributor, the lower precooling water distributor, the precooling drain pan, the precooling water storage tank, the fourth valve, the fourth temperature sensor, and the precooling water pump are positioned inside the shell, and the precooling surface cooler is installed in front of an air inlet direction of the lower precooling wet film.

Further, a chilled water supply pipe is connected to a liquid inlet end of the air-chilled water radiator, a liquid outlet end of the air-chilled water radiator is connected to a liquid inlet end on the primary side of the CDU device, and the chilled water supply pipe is further connected to the liquid inlet end on the primary side of the CDU device.

Further, the liquid outlet end of the air-chilled water radiator includes a cold water fan coil end, an inter-row chilled water end, or a water-cooled valve end.

Further, a liquid outlet end on the secondary side of the CDU device is interconnected to a liquid inlet end of the cold plate of the plate-type liquid cooling cabinet, and a liquid outlet end of the cold plate is interconnected to a liquid inlet end on the secondary side of the CDU device.

Further, a first valve is installed between the chilled water supply pipe and the liquid inlet end of the air-chilled water radiator, a first temperature sensor is installed at the liquid outlet end of the air-chilled water radiator, and the first valve adjusts a flow rate of chilled water entering the air-chilled water radiator based on the first temperature sensor. A second valve is installed between the chilled water supply pipe and the liquid inlet end on the primary side of the CDU device, a second temperature sensor is installed between the liquid outlet end of the air-chilled water radiator and the liquid inlet end on the primary side of the CDU device, and the second valve adjusts a flow rate of the chilled water entering the primary side of the CDU device based on the second temperature sensor.

Further, a third valve is installed between the liquid inlet end and the liquid outlet end on the primary side of the CDU device, a third temperature sensor is installed at the liquid outlet end on the secondary side of the CDU device, and the third valve adjusts a circulation speed of the primary side of the CDU device based on the third temperature sensor.

Further, the CDU device is arranged side by side with the plate-type liquid cooling cabinet, each of the air-chilled water radiators is coupled to one precooling module and corresponds to two of the plate-type liquid cooling cabinets, the cold water fan coil end of the air-chilled water radiator is arranged in front of the plate-type liquid cooling cabinet, and a closed hot aisle is formed between the plate-type liquid cooling cabinet and the cold water fan coil.

Further, number of the CDU devices is at least two, and the two CDU devices and the plate-type liquid cooling cabinet share a supply water loop and a return water loop on the same secondary side.

Beneficial effects of the technical solutions provided by the embodiments of the present disclosure are as below. An air-liquid fusion modular data center includes a machine room, a plate-type liquid cooling cabinet, an air-chilled water radiator, a precooling module, and a CDU device. The plate-type liquid cooling cabinet, the air-chilled water radiator, the precooling module, and the CDU device are positioned inside the machine room. A server is installed in the plate-type liquid cooling cabinet, and the air-chilled water radiator is coupled to the precooling module. The air-chilled water radiator forms a cooling water circulation together with the primary side of the CDU device; and the secondary side of the CDU device forms a cooling water circulation together with the cold plate of the plate-type liquid cooling cabinet. In this way, modularity of an air-liquid fusion heat dissipation apparatus in the data center is improved, water pipe loops of systems are recombined and arranged, cold source pipes are merged, and structures of the water pipe loops of the systems are optimized, to serve as an integrated solution to the data center. The cooling water can be recycled, heat dissipation costs and energy consumption can be reduced, building space required for the cold source can be reduced, and modularity level can be improved. Furthermore, the present disclosure also solves a problem where it is not cold indoors although the refrigeration is started because heat exchange between the chilled water and the hot air is adversely affected by accumulation of dust and dirt on fans of the air-chilled water radiator under the action of air extraction and air return due to long-term use. Based on the optimized water pipe system structure, a simplified control scheme is proposed. Different valves are used for water pipes with different control objectives, which not only improves safety of the system and saves energy, but also has a single control objective and is more stable in operation. The air-liquid fusion modular data center may be used for renovation of old buildings with existing chilled water systems, or prefabrication may be done to reduce on-site quantities.

### BRIEF DESCRIPTION OF THE DRAWINGS

To describe the technical solutions of the embodiments of the present disclosure more clearly, the accompanying drawings required for describing the embodiments will be briefly introduced below. Apparently, the accompanying drawings in the following description are merely some embodiments of the present disclosure. To those of ordinary skills in the art, other accompanying drawings may also be derived from these accompanying drawings without creative efforts.

FIG. 1 is a schematic diagram of a system modular structure of an air-liquid fusion modular data center according to an embodiment of the present disclosure;

FIG. 2 is a vertical view of a system modular structure of an air-liquid fusion modular data center according to an embodiment of the present disclosure;

FIG. 3 is an A-A side view of a system modular structure of an air-liquid fusion modular data center according to an embodiment of the present disclosure; and

FIG. 4 is a structural diagram of a precooling module of an air-liquid fusion modular data center according to an embodiment of the present disclosure.

### DETAILED DESCRIPTION

To make the objectives, technical solutions and advantages of the present disclosure clearer, the embodiments of the present disclosure will be further described below in detail with reference to the accompanying drawings.

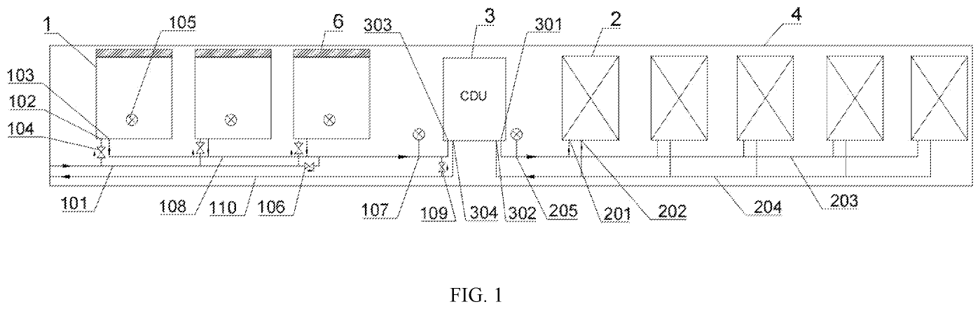

The embodiments of the present disclosure provide an air-liquid fusion modular data center, which includes: a machine room 4, a plate-type liquid cooling cabinet 2, an air-chilled water radiator 1, a precooling module 6, and a CDU device 3. The plate-type liquid cooling cabinet 2, the air-chilled water radiator 1 and the CDU device 3 are positioned inside the machine room 4. A server (not shown in the figure) is installed in the plate-type liquid cooling cabinet 2, and the air-chilled water radiator 1 is coupled to the precooling module 6. As shown in FIG. 1, the air-chilled water radiator 1 forms a cooling water circulation together with a primary side of the CDU device 3; and a secondary side of the CDU device forms a cooling water circulation together with a cold plate of the plate-type liquid cooling cabinet 2. The server is installed in the plate-type liquid cooling cabinet 2, and is close to the cold plate of the plate-type liquid cooling cabinet 2. Heat generated by the server during operation may be transferred to the cold plate through a surface shell of the server. A liquid outlet end 301 on the secondary side of the CDU device 3 is interconnected to a liquid inlet end 201 of the cold plate of the plate-type liquid cooling cabinet 2, and a liquid outlet end 202 of the cold plate is interconnected to a liquid inlet end 302 on the secondary side of the CDU device 3. That is, the CDU device 3 provides circulation power to the cooling water, such that the cooling water flows through the cold plates of a plurality of plate-type liquid cooling cabinets by means of a liquid cooling secondary supply water loop 203 and a liquid cooling secondary return water loop 204. In this case, the circulating cooling water formed in the cold plate of the plate-type liquid cooling cabinet 2 carries out heat exchange with heat generated by the server to reduce temperature of the server. Next, the cooling water flows back to the CDU device 3 through the liquid cooling secondary return water loop 204, and exchanges the heat from the secondary side to the primary side through the CDU device 3.

The chilled water supply pipe 101 is connected to a liquid inlet end 102 of the air-chilled water radiator 1, and a liquid outlet end 103 of the air-chilled water radiator 1 is connected to a liquid inlet end 303 on the primary side of the CDU device 3. To better regulate the temperature of the cooling water at the liquid inlet end 303 on the primary side of the CDU device 3, the chilled water supply pipe 101 may also be connected to the liquid inlet end 303 on the primary side of the CDU device 3 to optimize the water pipe system structure. To improve the safety and energy efficiency of the system and to ensure a single control target and more stable operation, different electrically operated water valves may be provided as flow switches for water pipes with different control objectives to simplify control schemes thereof.

Specifically, a first valve 104 is installed between the chilled water supply pipe 101 and the liquid inlet end 102 of the air-chilled water radiator 1, and a first temperature sensor 105 is installed at the liquid outlet end 103 of the air-chilled water radiator 1. The first valve 104 adjusts a flow rate of chilled water entering the air-chilled water radiator 1 based on the first temperature sensor 105 as the control target, thereby adjusting heat dissipation effects of the air-chilled water radiator 1 on hot air in the machine room 4. That is, the chilled water supply pipe 101 supplies cold water to the air-chilled water radiator 1. Number of the first valves 104 and number of the first temperature sensors 105 may be set according to the actual number of the air-chilled water radiators 1. That is, each air-chilled water radiator 1 corresponds to a set of first valve 104 and first temperature sensor 105.

A second valve 106 is installed between the chilled water supply pipe 101 and the liquid inlet end 303 on the primary side of the CDU device 3, and a second temperature sensor 107 is installed at the liquid inlet end 303 on the primary side of the CDU device 3. The second valve 106 adjusts a flow rate of the chilled water entering the primary side of the CDU device based on the second temperature sensor 107 as the control target. That is, the chilled water supply pipe 101 also supplies the cold water to the CDU device 3, such that the cooling water at the liquid outlet end 103 of the air-chilled water radiator 1 can be mixed with the cooling water in the chilled water supply pipe 101, which can reduce the temperature of the cooling water entering the primary side of the CDU device 3. When the second valve 106 is closed, only the air-chilled water radiator supply pipe 108 supplies water to the primary side of the CDU device 3. Therefore, the wider the second valve 106 is opened, the lower the cooling water temperature measured by the second temperature sensor 107 is; and the narrower the second valve 106 is opened, the higher the cooling water temperature measured by the second temperature sensor 107 is. The number of the second valve 106 and the number of the second temperature sensor 107 is both set to one.

A third valve 109 is installed between the liquid inlet end 303 and the liquid outlet end 304 on the primary side of the CDU device 3. The third valve 109 is arranged between a liquid cooling primary water supply pipe 108 (the air-chilled water radiator supply pipe 108) and a liquid cooling primary water return pipe 110 near the liquid inlet end 303 and the liquid outlet end 304 of the CDU device 3 on the primary side. The third valve 109 is a valve connected between a hot source and a cold source. A third temperature sensor 205 is installed at the liquid outlet end 301 on the secondary side of the CDU device 3, and the third valve 109 adjusts a water circulation speed of the primary side of the CDU device 3 based on the third temperature sensor 205 as the control target. That is, when the third valve 109 is opened narrower, the water flow rate on the primary side is controlled to be slower, resulting in poorer heat dissipation effects. Therefore, when the temperature at the third temperature sensor 205 is lower and thus no better heat dissipation effects are required, the third valve 109 may be opened narrower to slow down the flow rate, thus reducing energy consumption. When water temperature at the third temperature sensor 205 is higher and heat dissipation is poorer, it is required to increase the flow rate to improve the heat dissipation effects. In this case, the third valve 109 is opened wider to increase the flow rate of the liquid cooling primary water supply pipe 108 and the liquid cooling primary water return pipe 110, thereby achieving the effects of rapid heat dissipation. Both the number of the third valve 109 and the number of the third temperature sensor 205 are set to one.

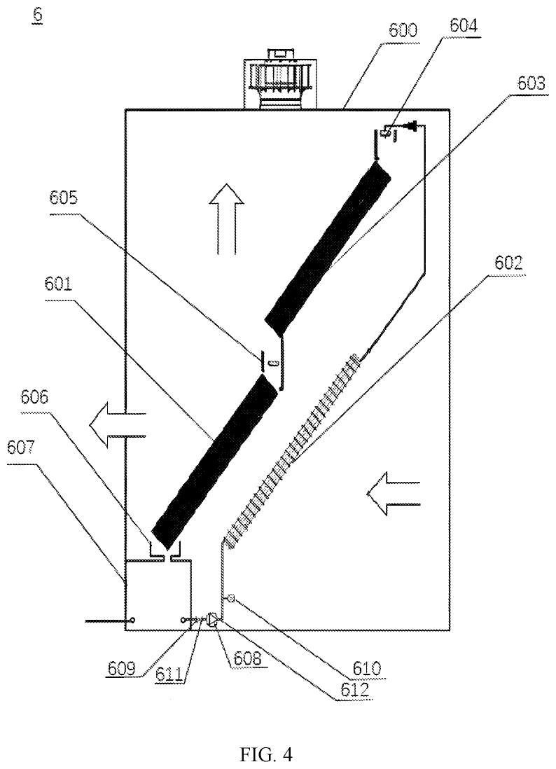

Further, to solve the problem where it is not cold indoors although the refrigeration is started, in addition to regular cleaning of fans, as shown in FIG. 4, a precooling module 6 is also arranged to cool external hot air entering the machine room 4 and devices such as the servers (not shown in the figure). In the present disclosure, precooling treatment is performed before evaporation and heat exchange between the external hot air and the air-chilled water radiator 1. The precooling module 6 adopts a double wet film design with upper and lower layers. A precooling surface cooler 602 is arranged in front of a lower precooling wet film 601 to cool the air entering the lower precooling wet film 601 and improve efficiency of gas-liquid heat exchange of the circulating water in the wet film, such that overall temperature of the circulating water in the precooling module 6 is reduced.

After the external hot air is precooled by means of heat exchange by the precooling surface cooler 602 positioned below the precooling module 6, temperature of precooled water at the lower precooling wet film 601 and temperature of the external hot air decrease. Furthermore, the external hot air undergoes evaporation and heat exchange through the upper precooling wet film 603 in the precooling module 6, and thus the temperature of the precooled water at the upper precooling wet film 603 and the temperature of the external hot air are higher than the temperature of the precooled water at the lower precooling wet film 601. After being precooled by the precooling module 6, the external hot air again undergoes gas-liquid heat exchange with the cold water supplied by the chilled water supply pipe 101 by means of the air-chilled water radiator 1. The cooled air enters the machine room 4 to reduce room temperature and temperature of the devices such as the servers, thus further helping to reduce the room temperature of the data center and the temperature of the devices such as the servers.

The precooling module 6 includes a shell 600, the precooling surface cooler 602, the upper precooling wet film 603, the lower precooling wet film 601, an upper precooling water distributor 604, a lower precooling water distributor 605, a precooling drain pan 606, a precooling water storage tank 607, a precooling water pump 608, a fourth valve 609, and a fourth temperature sensor 610. The precooling surface cooler 602, the upper precooling wet film 603, the lower precooling wet film 601, the upper precooling water distributor 604, the lower precooling water distributor 605, the precooling drain pan 606, the precooling water storage tank 607, the fourth valve 609, the fourth temperature sensor 610, and the precooling water pump 608 are positioned inside the shell 600. The upper precooling wet film 603 and the lower precooling wet film 601 are adjacent to an air inlet of the shell 600. The upper precooling water distributor 604 is positioned above the upper precooling wet film 603, and the lower precooling water distributor 605 is positioned below the lower precooling wet film 601. The lower precooling wet film 601 is positioned below the lower precooling water distributor 605, and the precooling surface cooler 602 is positioned in front of an air inlet direction of the lower precooling wet film 601. The precooling drain pan 606 is positioned below the lower precooling wet film 601, and the precooling water storage tank 607 is positioned below the precooling drain pan 606. A liquid inlet end 611 of the precooling water pump 608 is connected to the precooling water storage tank 607. The fourth valve 609 is arranged between the precooling water pump 608 and the precooling water storage tank 607. A liquid outlet end 612 of the precooling water pump 608 is provided with the fourth temperature sensor 610. A liquid outlet end 612 of the precooling water pump 608 is interconnected to one end of the precooling surface cooler 602, other end of the precooling surface cooler 602 is interconnected to the upper precooling water distributor 604, and the precooling water storage tank is provided with a liquid inlet.

Specifically, the fourth valve 609 adjusts the cooling effects of the precooling module 6 on the hot air inside the machine room 4 based on the fourth temperature sensor 610 as the control target. That is, the precooling module 6 supplies the cold air to the machine room 4 to cool the hot air. Number of the fourth valves 609 and number of the fourth temperature sensors 610 may be set according to actual number of the air-chilled water radiators 1. That is, each air-chilled water radiator 1 is correspondingly provided with one precooling module 6, and is correspondingly provided with a set of fourth valve 609 and fourth temperature sensor 610. When the precooling module 6 is started, the precooled water is pumped into the precooling surface cooler 602 through the precooling water pump 608, and undergoes a preliminary gas-liquid heat exchange with the external hot air, such that the temperature of the external hot air is decreased. The precooled water in the precooling surface cooler 602 increases in temperature, and the precooled water that rises in temperature is transported to the upper precooling water distributor 604, where the upper precooling wet film 603 is sprayed. Next, the precooled water flows into the lower precooling water distributor 605, where the lower precooling wet film 601 is sprayed. Next, the precooled water is collected in the precooling drain pan 606 and is stored in precooling water storage tank 607. Because the external hot air is precooled at the precooling surface cooler 602, temperature of the external air at the lower precooling wet film 601 below the precooling module 6 is lower than that of the external air at the upper precooling wet film 603. Furthermore, because the precooled water rises in temperature after heat exchange with the external hot air, the temperature of the precooled water sprayed on the upper precooling wet film 603 is higher than that of the precooled water in the lower precooling wet film 601. As a result, the external air with higher temperature above the precooling module 6 and the precooled water with higher temperature have higher evaporation efficiency, and direct heat exchange efficiency is higher below the precooling module 6. Thus, the external air with lower temperature can be obtained and transported to the machine room 4 for cooling.

Preferably, to reduce the heat of the server and lower the temperature of the server, the liquid outlet end 103 of the air-chilled water radiator 1 may use a cold water fan coil end, an inter-row chilled water end, or a water-cooled valve end, etc. To achieve better backup effects, even if a partial of coils go wrong, other coils can still ensure backup. The cold water fan coil end can better solve this problem. Furthermore, the cold water fan coil end has various types such as vertical and horizontal types, which can be set more flexibly according to needs. A position of the cold water fan coil end may be closer to a heat source to reduce more power consumption and ensure sufficient maintenance space. Moreover, heat from other low-power devices may also be dissipated through the cold water fan coil end. In one aspect, when the cold water fan coil end is closer to the server, wind resistance of the fan is smaller, and airflow distribution is smoother. By accelerating air flow around the device, indoor and outdoor air where the device such as the server is positioned is continuously recirculated, such that the air passes through the cold water coil and transfers the heat of the air to the chilled water, thus the air is cooled and taken out of the data center to maintain a constant space temperature, and the fan is lower in power consumption. In another aspect, there is difference between lower water temperature (15-32° C.) demand at the cold water fan coil end and higher water temperature (25-35° C.) demand on the primary side of the CDU device. The chilled water has larger temperature difference, and the return water has higher temperature. By utilizing natural water temperature difference for natural cooling, the device such as the server can be cooled down faster, which makes full use of natural cooling and is more energy-efficient on the whole. That is, by controlling air quantity and water quantity, heat dissipation costs and energy consumption can be further reduced.

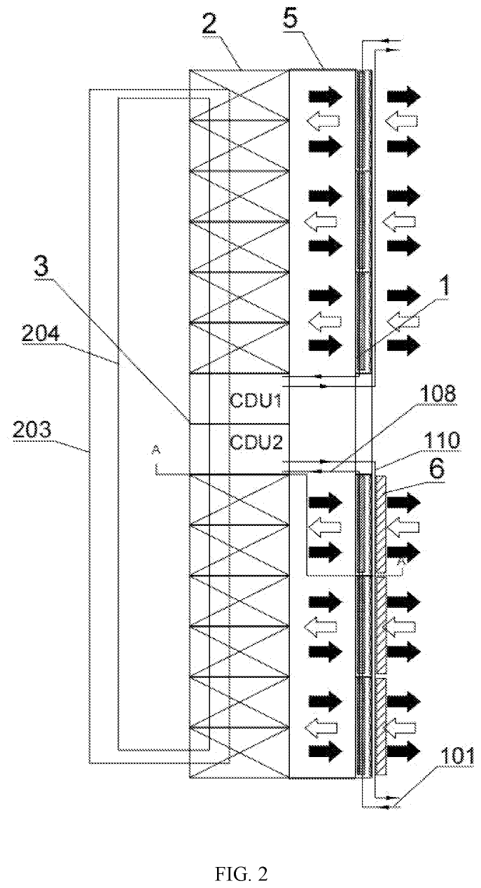

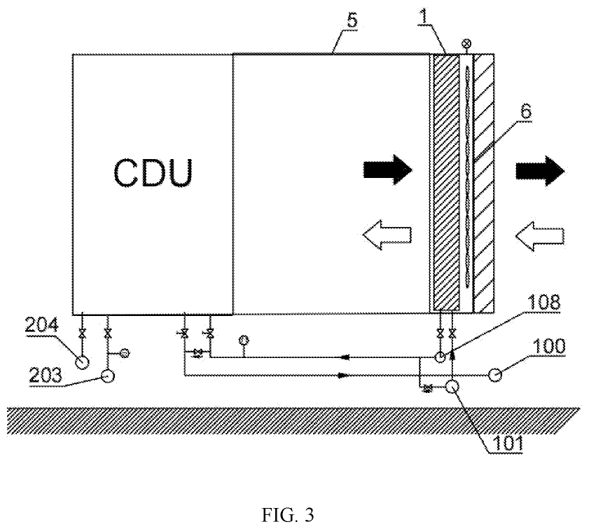

FIG. 2 shows a schematic diagram of a system modular structure of a data center. The CDU device 3 is arranged side by side with the plate-type liquid cooling cabinet 2. The cold water fan coil end 1 is arranged in another row in front of the plate-type liquid cooling cabinet 2. One side of each cold water fan coil end 1 corresponds to one precooling module 6, and other side of each cold water fan coil end 1 corresponds to two plate-type liquid cooling cabinets 2. A closed hot channel 5 is formed between the plate-type liquid cooling cabinet 2 and the cold water fan coil end 1. At least two CDU devices 3 are provided for mutual backup, and the at least two CDU devices 3 are closer to the plate-type liquid cooling cabinet 2, such that a secondary water pump has lower lift and lower power consumption, and is more energy-efficient on the whole. Specifically, the two CDU devices 3 and the plate-type liquid cooling cabinet 2 share a supply water loop 203 and a return water loop 204 on the same secondary side. As shown in FIG. 3, by raising a bottom and reserving space, each water pipe of the system is laid down, cold source pipes on the primary side are merged, and structures of the water pipes of the system are optimized, such that all the pipes are independent of each other and are arranged at intervals in parallel, to save space.

In the embodiments of the present disclosure, an air-liquid fusion modular data center includes a machine room 4, a plate-type liquid cooling cabinet 2, an air-chilled water radiator 1, a precooling module 6, and a CDU device 3. The plate-type liquid cooling cabinet 2, the air-chilled water radiator 1, the precooling module 6, and the CDU device 3 are positioned inside the machine room 4. A server is installed in the plate-type liquid cooling cabinet 2, and the air-chilled water radiator 1 is coupled to the precooling module 6. The air-chilled water radiator 1 forms a cooling water circulation together with the primary side of the CDU device 3; and the secondary side of the CDU device 3 forms a cooling water circulation together with the cold plate of the plate-type liquid cooling cabinet 2. In the present disclosure, modularity of an air-liquid fusion heat dissipation apparatus in the data center is improved, water pipes of the systems are recombined and arranged, cold source pipes are merged, structures of the water pipes of the systems are optimized, and a control scheme is simplified, to serve as an integrated solution to the data center. The cooling water can be recycled, and heat dissipation costs and energy consumption can be reduced. Furthermore, the present disclosure also solves a problem where it is not cold although the refrigeration is started, building space required for a cold source is reduced, and modularity level can be improved. Moreover, the data center has a single control target, and is more stable in operation.

The embodiments described above are only illustrated as preferred embodiments of the present disclosure, and are not intended to limit the present disclosure. All modifications, equivalent substitutions and improvements made within the spirit and principles of the present disclosure shall fall within the protection scope of the present disclosure.

What is claimed is:

1. An air-liquid fusion modular data center comprising: a machine room, a plate-type liquid cooling cabinet, an air-chilled water radiator, a precooling module, and a CDU device, wherein the plate-type liquid cooling cabinet, the air-chilled water radiator, the precooling module, and the CDU device are positioned inside the machine room, a server is installed in the plate-type liquid cooling cabinet, and the air-chilled water radiator is coupled to the precooling module;
the air-chilled water radiator forms a cooling water circulation together with a primary side of the CDU device; and a secondary side of the CDU device forms a cooling water circulation together with a cold plate of the plate-type liquid cooling cabinet; and
a fourth valve is arranged between a precooling water pump in the precooling module and a precooling water storage tank, a fourth temperature sensor is installed at a liquid outlet end of the precooling water pump, and the fourth valve adjusts a cooling effect of the precooling module on hot air inside the machine room based on the fourth temperature sensor.

2. The data center according to claim 1, wherein the precooling module adopts a double wet film design with upper and lower layers.

3. The data center according to claim 2, wherein the precooling module comprises a shell, a precooling surface cooler, an upper precooling wet film, a lower precooling wet film, an upper precooling water distributor, a lower precooling water distributor, a precooling drain pan, the precooling water storage tank, the precooling water pump, the fourth valve, and the fourth temperature sensor; the precooling surface cooler, the upper precooling wet film, the lower precooling wet film, the upper precooling water distributor, the lower precooling water distributor, the precooling drain pan, the precooling water storage tank, the fourth valve, the fourth temperature sensor, and the precooling water pump are positioned inside the shell, and the precooling surface cooler is installed in front of an air inlet direction of the lower precooling wet film.

4. The data center according to claim 1, wherein a chilled water supply pipe is connected to a liquid inlet end of the air-chilled water radiator, and a liquid outlet end of the air-chilled water radiator is connected to a liquid inlet end on the primary side of the CDU device; and
the chilled water supply pipe is further connected to the liquid inlet end on the primary side of the CDU device.

5. The data center according to claim 4, wherein the liquid outlet end of the air-chilled water radiator comprises a cold water fan coil end, an inter-row chilled water end, or a water-cooled valve end.

6. The data center according to claim 1, wherein
a liquid outlet end on the secondary side of the CDU device is interconnected to a liquid inlet end of the cold plate of the plate-type liquid cooling cabinet, and a liquid outlet end of the cold plate is interconnected to a liquid inlet end on the secondary side of the CDU device.

7. The data center according to claim 4, wherein a first valve is installed between the chilled water supply pipe and the liquid inlet end of the air-chilled water radiator, a first temperature sensor is installed at the liquid outlet end of the air-chilled water radiator, and the first valve adjusts a flow rate of chilled water entering the air-chilled water radiator based on the first temperature sensor; and
a second valve is installed between the chilled water supply pipe and the liquid inlet end on the primary side of the CDU device, a second temperature sensor is installed between the liquid outlet end of the air-chilled water radiator and the liquid inlet end on the primary side of the CDU device, and the second valve adjusts a flow rate of the chilled water entering the primary side of the CDU device based on the second temperature sensor.

8. The data center according to claim 7, wherein
a third valve is installed between the liquid inlet end and the liquid outlet end on the primary side of the CDU device, a third temperature sensor is installed at the liquid outlet end on the secondary side of the CDU device, and the third valve adjusts a circulation speed of the primary side of the CDU device based on the third temperature sensor.

9. The data center according to claim 1, wherein the CDU device is arranged side by side with the plate-type liquid cooling cabinet, each of the air-chilled water radiators is coupled to one precooling module and corresponds to two of the plate-type liquid cooling cabinets, the cold water fan coil end of the air-chilled water radiator is arranged in front of the plate-type liquid cooling cabinet, and a closed hot aisle is formed between the plate-type liquid cooling cabinet and the cold water fan coil.

10. The data center according to claim 1, wherein number of the CDU devices is at least two, and the two CDU devices and the plate-type liquid cooling cabinet share a supply water loop and a return water loop on a same secondary side.
